(19) United States
(12) Patent Application Publication
(10) Pub. No.: US 2013/0080857 A1
(43) Pub. Date: Mar. 28, 2013

(54) FLASH MEMORY CONTROLLER ADAPTIVELY SELECTING ERROR-CORRECTION SCHEME ACCORDING TO NUMBER OF PROGRAM/ERASE CYCLES OF FLASH MEMORY

(71) Applicants: Yao-Nan Lee, Tainan City (TW); Shin-Shiuan Cheng, Tainan City (TW)

(72) Inventors: Yao-Nan Lee, Tainan City (TW); Shin-Shiuan Cheng, Tainan City (TW)

(21) Appl. No.: 13/239,425

(22) Filed: Sep. 22, 2011

(51) Int. Cl. H03M 13/05; G06F 11/10

(52) U.S. Cl. 714/773; 714/E11.034

(57) ABSTRACT

A flash memory controller includes an encoding block, a decoding block and a control unit. The encoding block is utilized for encoding raw bits with a target forward error-correction (FEC) coding scheme selected from a plurality of candidate FEC coding schemes. The decoding block is utilized for decoding encoded bits with a target FEC decoding scheme selected from a plurality of candidate FEC decoding schemes, wherein the target FEC decoding scheme corresponds to the target FEC coding scheme. The control unit is coupled to the encoding block and the decoding block, and utilized for controlling a selection of the target FEC coding scheme utilized by the encoding block and a selection of the target FEC decoding scheme utilized by the decoding block according to a number of program/erase cycles of a flash memory.

### BACKGROUND OF THE INVENTION

1. Field of the Invention

The disclosed embodiments of the present invention relate to error-correction for a flash memory, and more particularly, to a flash memory controller adaptively selecting a forward error-correction (FEC) coding/decoding scheme according to a number of program/erase cycles of the flash memory.

2. Description of the Prior Art

As the size of a flash memory cell keeps scaling down, the reliability of data access of the flash memory decreases. Therefore, advanced forward error-correction (FEC) codes, such as low-density parity-check (LDPC) codes, are adopted to ensure the integrity of data storage. The performance of LDPC codes highly depends on a memory-cell threshold-voltage distribution. However, due to tunnel oxide degradation, a threshold-voltage of a memory cell differs when the number of program/erase cycles of the memory cell increases, which results in different threshold-voltage distributions and inevitably degrades the error-correction performance of the originally-designed LDPC codes.

### SUMMARY OF THE INVENTION

In accordance with exemplary embodiments of the present invention, flash memory controllers employing multiple forward error-correction (FEC) coding/decoding schemes for a flash memory according to a number of program/erase cycles of the flash memory are proposed to solve the above-mentioned problem.

According to a first aspect of the present invention, an exemplary flash memory controller is disclosed. The flash memory controller includes an encoding block, a decoding block and a control unit. The encoding block is utilized for encoding raw bits with a target forward error-correction (FEC) coding scheme selected from a plurality of candidate FEC coding schemes. The decoding block is utilized for decoding encoded bits with a target FEC decoding scheme selected from a plurality of candidate FEC decoding schemes, wherein the target FEC decoding scheme corresponds to the target FEC coding scheme. The control unit is coupled to the encoding block and the decoding block, for controlling a selection of the target FEC coding scheme utilized by the encoding block and a selection of the target FEC decoding scheme utilized by the decoding block according to a number of program/erase cycles of a flash memory.

According to a second aspect of the present invention, an exemplary flash memory controller is disclosed. The flash memory controller includes an encoding block and a control unit. The encoding block is utilized for encoding raw bits with a target FEC coding scheme selected from a plurality of candidate FEC coding schemes. The control unit is coupled to the encoding block, for controlling a selection of the target FEC coding scheme utilized by the encoding block according to a number of program/erase cycles of a flash memory.

According to a third aspect of the present invention, an exemplary flash memory controller is disclosed. The flash memory controller includes a decoding block and a control unit. The decoding block is utilized for decoding encoded bits with a target FEC decoding scheme selected from a plurality of candidate FEC decoding schemes, wherein the target FEC decoding scheme corresponds to the target FEC coding scheme. The control unit is coupled to the decoding block, for controlling a selection of the target FEC decoding scheme utilized by the decoding block according to a number of program/erase cycles of a flash memory.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a flash memory controller according to an embodiment of the present invention.

FIG. 2 is a flowchart illustrating operations of a flash memory controller according to an embodiment of the present invention.

### DETAILED DESCRIPTION

Certain terms are used throughout the description and following claims to refer to particular components. As one skilled in the art will appreciate, manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is electrically connected to another device, that connection may be through a direct electrical connection, or through an indirect electrical connection via other devices and connections.

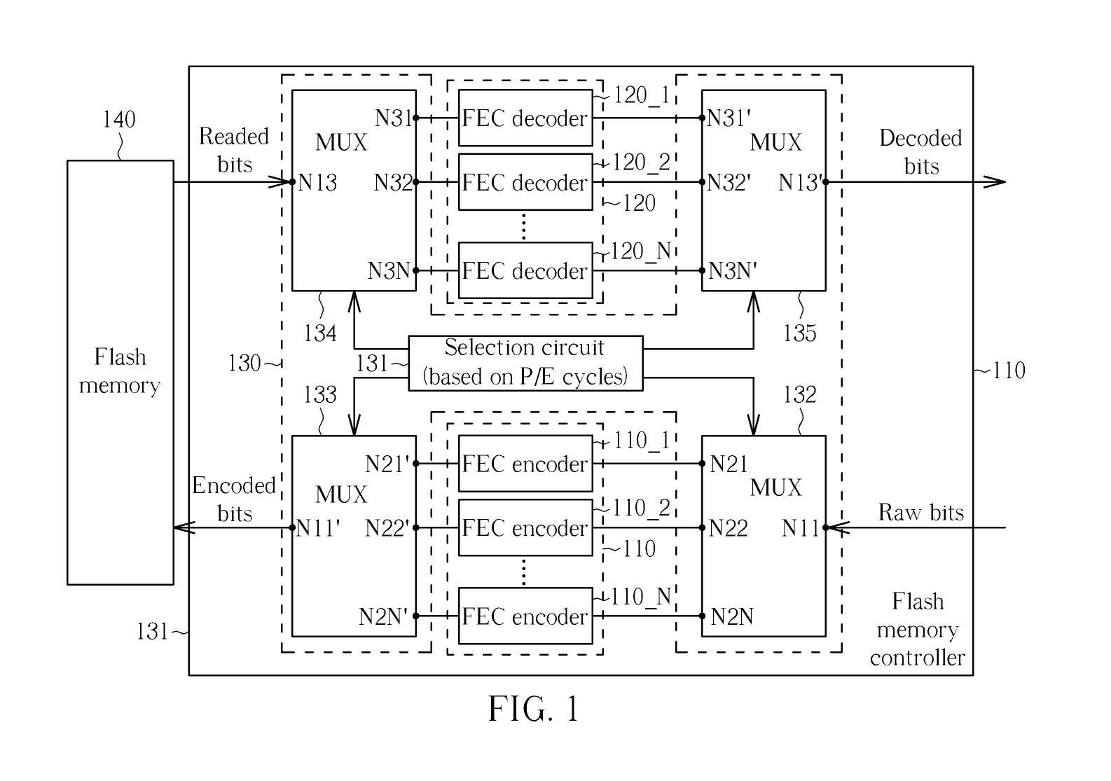

Please refer to FIG. 1, which is a schematic diagram of a flash memory controller 100 according to an embodiment of the present invention. The flash memory controller 100 includes, but not limited to, an encoding block 110, a decoding block 120 and a control unit 130. The control unit 130 is coupled to the encoding block 110 and the decoding block 120, and utilized for controlling a selection of a target forward error-correction (FEC) coding scheme (e.g., a low-density parity-check (LDPC) coding scheme) from a plurality of candidate FEC coding schemes and a selection of a corresponding target FEC decoding scheme (e.g., an LDPC decoding scheme) from a plurality of candidate FEC decoding schemes according to the number of program/erase cycles of a flash memory 140, where the encoding block 110 utilizes the selected target FEC coding scheme to encode raw bits, and the decoding block 120 utilizes the target FEC decoding scheme to decode the encoded bits.

In an exemplary design, the encoding block 110 includes a plurality of candidate encoders 110_1˜110_N which employ the candidate FEC coding schemes, respectively. The decoding block 120 includes a plurality of candidate decoders 120_1˜120_N which employ the candidate FEC decoding schemes, respectively. The control unit 130 is coupled to the candidate encoders 110_1˜110_N and the candidate decoders 120_1˜120_N, and refers to the number of program/erase cycles to select a target encoder employing the target FEC coding scheme from the candidate encoders 110_1˜110_N and select a target decoder employing the target FEC decoding scheme from the candidate decoders 120_1˜120_N.

In addition, the control unit 130 includes a selection circuit 131, a first multiplexer (MUX) 132, a second multiplexer 133, a third multiplexer 134 and a fourth multiplexer 135. The selection circuit 131 is coupled to the first multiplexer 132, the second multiplexer 133, the third multiplexer 134 and the fourth multiplexer 135, and operates according to the number of program/erase cycles. As shown in FIG. 1, the first multiplexer 132 has a first input end N11 for receiving the raw bits and a plurality of first output ends N21˜N2N respectively coupled to the candidate encoders 110_1˜110_N, and the selection circuit 131 controls the first multiplexer 132 to couple the first input end N11 to a first output end (e.g., N21) to which the target encoder (e.g., FEC encoder 110_1) is coupled. The second multiplexer 133 has a plurality of second input ends N21′˜N2N′ respectively coupled to the candidate encoders 110_1˜110_N and a second output end N11′ coupled to the flash memory 140, and the selection circuit 131 controls the second multiplexer 133 to couple the second output end N11′ to a second input end (e.g., N21′) to which the target encoder (e.g., FEC encoder 110_1) is coupled. The third multiplexer 134 has a third input end N13 coupled to the flash memory 140 and a plurality of third output ends N31˜N3N respectively coupled to the candidate decoders 120_1˜120_N, and the selection circuit 131 controls the third multiplexer 134 to couple the third input end N13 to a third output end (e.g., N31) to which the target decoder (e.g., FEC decoder 120_1) is coupled. The fourth multiplexer 135 has a plurality of fourth input ends N31′˜N3N′ respectively coupled to the candidate decoders 120_1˜120_N and a fourth output end N13′ for sending the decoded bits, and the selection circuit 131 controls the fourth multiplexer 135 to couple the fourth output end N13′ to a fourth input end (e.g., N31′) to which the target decoder (e.g., FEC decoder 120_1) is coupled.

Please note that, the aforementioned embodiment is for illustrative purposes only, and is not meant to be limitations of the present invention. Those skilled in the art should readily appreciate that making modifications to the aforementioned embodiment without departing from the spirit of the present invention is feasible. For example, in one alternative design, the candidate encoders 110_1˜110_N may be integrated into one single encoder with multiple FEC coding modes, and the control unit 130 may be utilized to configure the integrated encoder to operate in a selected FEC coding mode. In another alternative design, the candidate decoders 120_1˜110_N may be integrated into one single decoder with multiple FEC decoding modes, and the control unit 130 may be utilized to configure the integrated decoder to operate in a selected FEC decoding mode. In yet another alternative design, the candidate encoders 110_1˜110_N may be integrated into one single encoder with multiple FEC coding modes, and the candidate decoders 120_1-18 120_N may also be integrated into one single decoder with multiple FEC decoding modes.

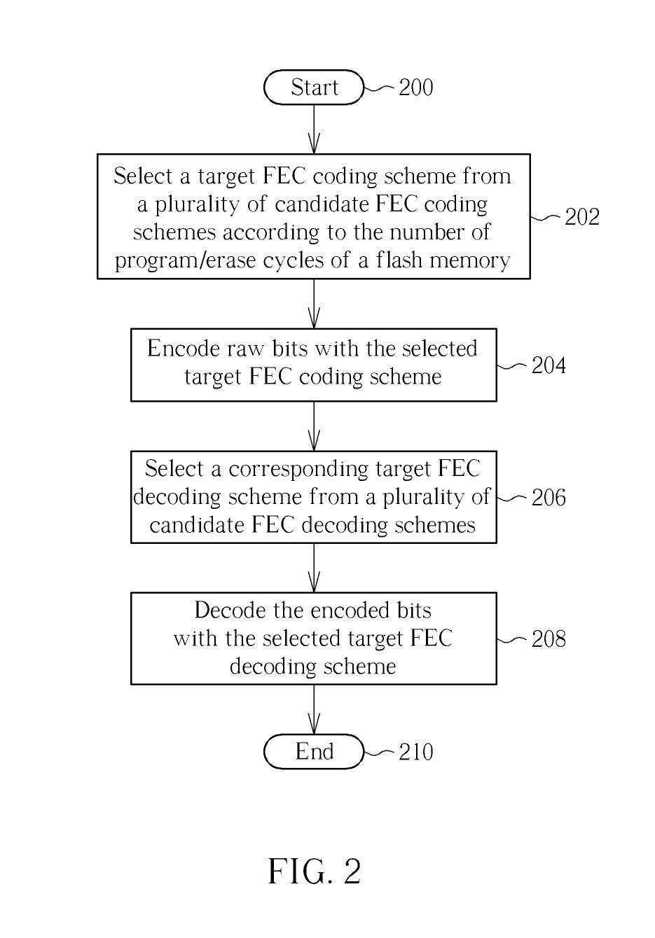

The operations of the flash memory controller 100 may be briefly summarized as a process shown in FIG. 2. FIG. 2 is a flowchart illustrating operations of a flash memory controller according to an embodiment of the present invention. Please note that if the result is substantially the same, the steps are not required to be executed in the exact order shown in FIG. 2.

Step 200: Start.

Step 202: Select a target FEC coding scheme from a plurality of candidate FEC coding schemes according to the number of program/erase cycles of a flash memory.

Step 204: Encode raw bits with the selected target FEC coding scheme.

Step 206: Select a corresponding target FEC decoding scheme from a plurality of candidate FEC decoding schemes.

Step 208: Decode the encoded bits with the selected target FEC decoding scheme.

Step 210: End.

To sum up, the present invention employs several FEC codes pre-designed based on different memory-cell threshold-voltage distributions measured at different program/erase cycles, and then adaptively selects the most suitable FEC code based on the number of program/erase cycles for error-correction. Since the memory-cell threshold-voltage distribution is a critical factor to the error-correction for the flash memory, the use of the exemplary flash memory controller according to the present invention can enhance the error-correction performance and increase the reliability of data access of the flash memory.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A flash memory controller, comprising:
an encoding block, for encoding raw bits with a target forward error-correction (FEC) coding scheme selected from a plurality of candidate FEC coding schemes;
a decoding block, for decoding encoded bits with a target FEC decoding scheme selected from a plurality of candidate FEC decoding schemes, wherein the target FEC decoding scheme corresponds to the target FEC coding scheme; and
a control unit, coupled to the encoding block and the decoding block, for controlling a selection of the target FEC coding scheme utilized by the encoding block and a selection of the target FEC decoding scheme utilized by the decoding block according to a number of program/erase cycles of a flash memory.

2. The flash memory controller of claim 1, wherein the encoding block comprises a plurality of candidate encoders employing the plurality of candidate FEC coding schemes, respectively; the decoding block comprises a plurality of candidate decoders employing the plurality of candidate FEC decoding schemes, respectively; and the control unit is coupled to the plurality of candidate encoders and the plurality of candidate decoders, and refers to the number of program/erase cycles to select a target encoder employing the target FEC coding scheme from the plurality of candidate encoders and select a target decoder employing the target FEC decoding scheme from the plurality of candidate decoders.

3. The flash memory controller of claim 2, wherein the control unit comprises:
a selection circuit, operating according to the number of program/erase cycles;
a first multiplexer, having a first input end for receiving the raw bits and a plurality of first output ends respectively coupled to the plurality of candidate encoders, wherein the first multiplexer is controlled by the selection circuit to couple the first input end to a first output end to which the target encoder is coupled;
a second multiplexer, having a plurality of second input ends respectively coupled to the plurality of candidate encoders and a second output end coupled to the flash memory, wherein the second multiplexer is controlled by the selection circuit to couple a second input end to which the target encoder is coupled to the second output end;
a third multiplexer, having a third input end coupled to the flash memory and a plurality of third output ends respectively coupled to the plurality of candidate decoders, wherein the third multiplexer is controlled by the selection circuit to couple the third input end to a third output end to which the target decoder is coupled; and
a fourth multiplexer, having a plurality of fourth input ends respectively coupled to the plurality of candidate decoders and a fourth output end for sending the decoded bits, wherein the fourth multiplexer is controlled by the selection circuit to couple a fourth input end to which the target decoder is coupled to the fourth output end.

4. The flash memory controller of claim 1, wherein each of the plurality of candidate FEC coding schemes is a low-density parity-check (LDPC) coding scheme, and each of the plurality of candidate FEC decoding schemes is an LDPC decoding scheme.

5. A flash memory controller, comprising:
an encoding block, for encoding raw bits with a target forward error-correction (FEC) coding scheme selected from a plurality of candidate FEC coding schemes; and
a control unit, coupled to the encoding block, for controlling a selection of the target FEC coding scheme utilized by the encoding block according to a number of program/erase cycles of a flash memory.

6. The flash memory controller of claim 5, wherein the encoding block comprises a plurality of candidate encoders employing the plurality of candidate FEC coding schemes, respectively; and the control unit is coupled to the plurality of candidate encoders, and refers to the number of program/erase cycles to select a target encoder employing the target FEC coding scheme from the plurality of candidate encoders.

7. The flash memory controller of claim 6, wherein the control unit comprises:
a selection circuit, operating according to the number of program/erase cycles;
a first multiplexer, having a first input end for receiving the raw bits and a plurality of first output ends respectively coupled to the plurality of candidate encoders, wherein the first multiplexer is controlled by the selection circuit to couple the first input end to a first output end to which the target encoder is coupled; and
a second multiplexer, having a plurality of second input ends respectively coupled to the plurality of candidate encoders and a second output end coupled to the flash memory, wherein the second multiplexer is controlled by the selection circuit to couple a second input end to which the target encoder is coupled to the second output end.

8. The flash memory controller of claim 5, wherein each of the plurality of candidate FEC coding schemes is a low-density parity-check (LDPC) coding scheme.

9. A flash memory controller, comprising:
a decoding block, for decoding encoded bits with a target FEC decoding scheme selected from a plurality of candidate FEC decoding schemes, wherein the target FEC decoding scheme corresponds to the target FEC coding scheme; and
a control unit, coupled to the decoding block, for controlling a selection of the target FEC decoding scheme utilized by the decoding block according to a number of program/erase cycles of a flash memory.

10. The flash memory controller of claim 9, wherein the decoding block comprises a plurality of candidate decoders employing the plurality of candidate FEC decoding schemes, respectively; and the control unit is coupled to and the plurality of candidate decoders, and refers to the number of program/erase cycles to select a target decoder employing the target FEC decoding scheme from the plurality of candidate decoders.

11. The flash memory controller of claim 10, wherein the control unit comprises:
a selection circuit, operating according to the number of program/erase cycles;
a first multiplexer, having a first input end coupled to the flash memory and a plurality of first output ends respectively coupled to the plurality of candidate decoders, wherein the first multiplexer is controlled by the selection circuit to couple the first input end to a first output end to which the target decoder is coupled; and
a second multiplexer, having a plurality of second input ends respectively coupled to the plurality of candidate decoders and a second output end for sending the decoded bits, wherein the second multiplexer is controlled by the selection circuit to couple a second input end to which the target decoder is coupled to the second output end.

12. The flash memory controller of claim 9, wherein each of the plurality of candidate FEC decoding schemes is an LDPC decoding scheme.
